(19) United States
(12) Patent Application Publication
(10) Pub. No.: US 2023/0402431 A1
(43) Pub. Date: Dec. 14, 2023

(54) SEMICONDUCTOR DEVICE AND MANUFACTURING METHOD THEREOF

(71) Applicant: Kioxia Corporation, Tokyo (JP)

(72) Inventor: Haruo MIKI, Yokohama (JP)

(73) Assignee: Kioxia Corporation, Tokyo (JP)

(21) Appl. No.: 18/330,462

(22) Filed: Jun. 7, 2023

(30) Foreign Application Priority Data
Jun. 9, 2022 (JP) 2022-093908

(51) Int. Cl. H01L 25/065; H01L 23/00

(52) U.S. Cl. CPC H01L 25/0657; H01L 24/73; H01L 24/48; H01L 24/32; H01L 2224/73265; H01L 2224/48227; H01L 2224/32225; H01L 2225/0651; H01L 2224/04042; H01L 2924/3512

(57) ABSTRACT

A semiconductor device according to the present embodiment includes a substrate, a first semiconductor chip, a second semiconductor chip, a bonding layer, and a member. The substrate has a first surface. The first semiconductor chip is provided on the first surface. The second semiconductor chip is provided above the first semiconductor chip, has a second surface facing the first surface and the first semiconductor chip, and coats the first semiconductor chip as viewed from a direction substantially perpendicular to the first surface. The bonding layer is provided between the second surface and both the first surface and the first semiconductor chip. The member is provided on at least part of an outer periphery of the bonding layer as viewed from the direction substantially perpendicular to the first surface.

### CROSS-REFERENCE TO RELATED APPLICATIONS

This application is based upon and claims the benefit of priority from the prior Japanese Patent Application No. 2022-093908, filed on Jun. 9, 2022, the entire contents of which are incorporated herein by reference.

### FIELD

The embodiments of the present invention relate to a semiconductor device and a manufacturing method thereof.

### BACKGROUND

In a package structure of a semiconductor device, there is occasionally a case where a memory chip is arranged so as to cover a controller chip on the substrate with a thick DAF (Die Attach Film).

### BRIEF DESCRIPTION OF THE DRAWINGS

FIG. 1 is a cross sectional view showing an example of a configuration of a semiconductor device according to a first embodiment;

FIG. 2 is a plan view showing an example of positional relationship between a wiring substrate, a semiconductor chip, a bonding layer, and a member in FIG. 1;

FIG. 3A is a view showing an example of a manufacturing method of a semiconductor device according to the first embodiment;

FIG. 3B is a view showing an example of the manufacturing method of a semiconductor device, succeeding to FIG. 3A;

FIG. 3C is a view showing an example of the manufacturing method of a semiconductor device, succeeding to FIG. 3B;

FIG. 3D is a view showing an example of the manufacturing method of a semiconductor device, succeeding to FIG. 3C;

FIG. 3E is a view showing an example of the manufacturing method of a semiconductor device, succeeding to FIG. 3D;

FIG. 4A is a view showing an example of a manufacturing method of a semiconductor device according to the first embodiment;

FIG. 4B is a view showing an example of the manufacturing method of a semiconductor device, succeeding to FIG. 4A;

FIG. 4C a view showing an example of the manufacturing method of a semiconductor device, succeeding to FIG. 4B;

FIG. 4D a view showing an example of the manufacturing method of a semiconductor device, succeeding to FIG. 4C;

FIG. 4E a view showing an example of the manufacturing method of a semiconductor device, succeeding to FIG. 4D;

FIG. 4F a view showing an example of the manufacturing method of a semiconductor device, succeeding to FIG. 4E;

FIG. 5 is a cross sectional view showing an example of a configuration of a semiconductor device according to a comparative example;

FIG. 6 is a plan view showing an example of positional relationship between a wiring substrate, a semiconductor chip, and a member according to a modification

FIG. 7 is a cross sectional view showing an example of a configuration of a semiconductor device according to a second embodiment; and

FIG. 8 is a cross sectional view showing an example of a configuration of a semiconductor device according to a third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a wiring substrate on which semiconductor chips are provided is assumed as “an upper direction”. Therefore, the term “upper direction” or “lower direction” occasionally differs from an upper direction or a lower direction based on a gravitational acceleration direction. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes: a substrate; a first semiconductor chip; a second semiconductor chip; a bonding layer; and a member. The substrate has a first surface. The first semiconductor chip is provided on the first surface. The second semiconductor chip is provided above the first semiconductor chip, has a second surface facing the first surface and the first semiconductor chip, and coats the first semiconductor chip as viewed from a direction substantially perpendicular to the first surface. The bonding layer is provided between the second surface and both the first surface and the first semiconductor chip. The member is provided on at least part of an outer periphery of the bonding layer as viewed from the direction substantially perpendicular to the first surface.

### First Embodiment

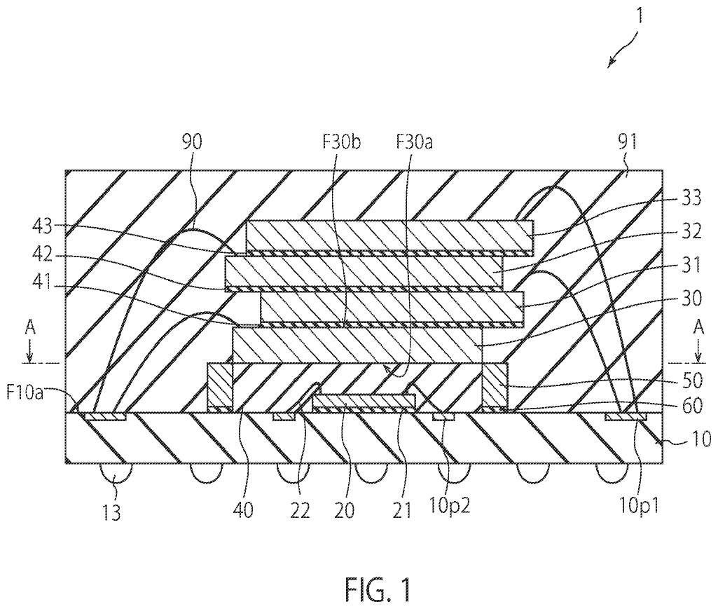

FIG. 1 is a cross sectional view showing an example of a configuration of a semiconductor device 1 according to a first embodiment. The semiconductor device 1 includes a wiring substrate semiconductor chips 20 and 30 to 33, bonding layers 40 to 43, a member 50, a bonding layer 60, bonding wires 90, and a sealing resin 91. An example of the semiconductor device 1 is a package of NAND flash memories.

The wiring substrate 10 may be a printed circuit board or an interposer including wiring layers (not shown) and insulating layers (not shown). For the wiring layers, there is used, for example, a low-resistance metal such as copper, nickel, or an alloy of these. For the insulating layers, there is used, for example, an insulative material such as a glass epoxy resin. The wiring substrate 10 may have a multilayer wiring structure configured by stacking a plurality of wiring layers and a plurality of insulating layers. Like an interposer, for example, the wiring substrate 10 may have through electrodes (not shown) penetrating its front surface and back surface.

On a surface F10a as a front surface (upper surface) of the wiring substrate 10, there are provided pads 10p1 and 10p2 connected to the wiring layers. The surface F10a is an example of a first surface.

Metal bumps 13 are provided on a back surface (lower surface) of the wiring substrate 10. The metal bumps 13 are provided for electrically connecting not-shown other components to the wiring substrate 10.

The semiconductor chip 20 is provided on the front surface (surface F10a) side of the wiring substrate 10. The semiconductor chip 20 is bonded to the wiring substrate 10 via a bonding layer 21. An example of the semiconductor chip 20 is a controller chip which controls a memory chip. On a surface (front surface), of the semiconductor chip 20, that is on the opposite side to a surface thereof facing the wiring substrate 10, not-shown semiconductor elements are provided. For example, the semiconductor elements may be CMOS (Complementary Metal Oxide Semiconductor) circuits constituting the controller. Bonding wires 22 electrically connect the pads 10p2 provided on the front surface of the wiring substrate 10 to pads (not shown) provided on the front surface of the semiconductor chip 20.

The semiconductor chip 30 is bonded to an upper portion above the semiconductor chip 20 via the bonding layer 40. An example of the semiconductor chip 30 is a memory chip including a NAND flash memory. The semiconductor chip 30 has semiconductor elements (not shown) on its front surface. For example, the semiconductor elements may be a memory cell array and its peripheral circuit (CMOS circuit). The memory cell array may be a three-dimensional memory cell array having a plurality of memory cells three-dimensionally arranged. Moreover, the semiconductor chip 31 is bonded onto the semiconductor chip 30 via the bonding layer 41. The semiconductor chip 32 is bonded onto the semiconductor chip 31 via the bonding layer 42. The semiconductor chip 33 is bonded onto the semiconductor chip 32 via the bonding layer 43. As with the semiconductor chip 30, an example of each of the semiconductor chips 31 to 33 is a memory chip including a NAND flash memory. The semiconductor chips 30 to 33 may be the same memory chips. In the figure, the semiconductor chips 30 to 33 as four memory chips, along with the semiconductor chip 20 as a controller chip, are stacked. Nevertheless, the number of stacked semiconductor chips may be three or less, or five or more.

More in detail, the semiconductor chip 30 has a surface F30a, a surface F30b that is on the opposite side of the surface F30a, and the bonding layer 40 on the surface F30a. The surface F30a is a surface that faces both the surface F10a of the wiring substrate 10 and the semiconductor chip 20. The surface F30a is an example of a second surface. The surface F30b is an example of a third surface.

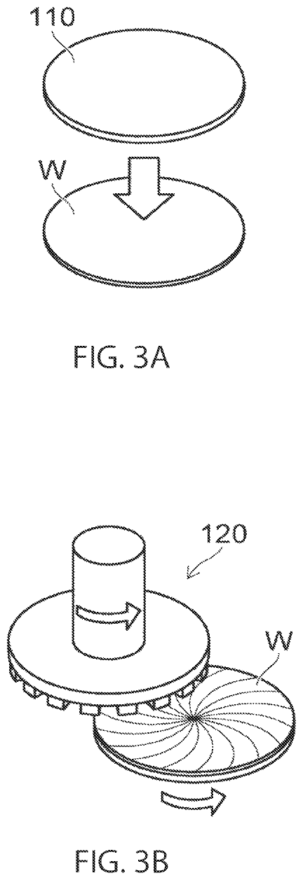

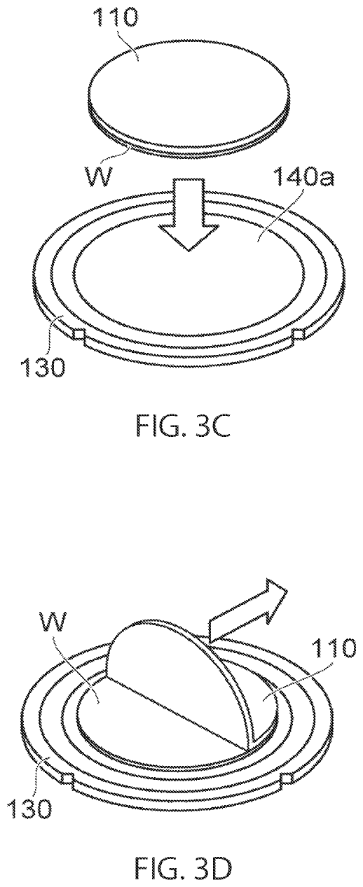

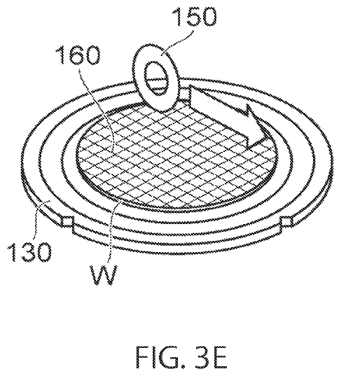

Moreover, the bonding layer 40 is thicker than the bonding layers 41 to 43. The bonding layer 40 is provided such that the semiconductor chip 20 and the bonding wires 22 are embedded therein (so as to coat the semiconductor chip 20 and the bonding wires 22). Namely, the bonding layer 40 is provided between the surface F30a of the semiconductor chip 30 and both the surface F10a of the wiring substrate and the semiconductor chip 20. Moreover, lateral surfaces of the bonding layer 40 are approximately parallel to lateral surfaces of the semiconductor chip 30 existing between the surface F30a and the surface F30b. Moreover, a width of the bonding layer 40 is approximately equal to a width of the semiconductor chip 30. Notably, each width means a width in the direction substantially parallel to the surface F10a. This is because a wafer on which a bonding layer is pasted is divided into separate pieces by dicing as described later with reference to FIG. 3A to FIG. 3E.

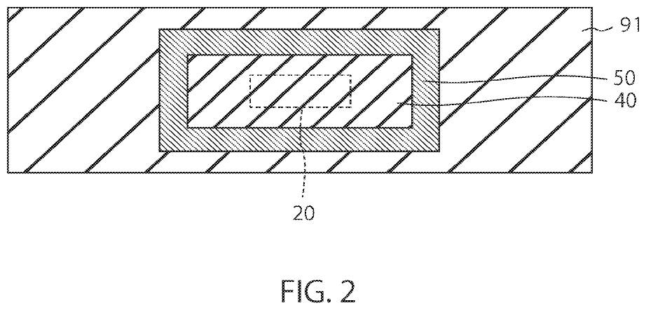

The member 50 is provided on the outer periphery of the bonding layer 40. The member 50 is bonded to the wiring substrate 10 via the bonding layer 60. Notably, details of arrangement of the member 50 is described later with reference to FIG. 2. Moreover, in the example shown in FIG. 1, a height of an upper surface of the member 50 is approximately equal to a height of the surface F30a of the semiconductor chip 30.

Each bonding wire 90 is connected to any pads of the wiring substrate 10 and the semiconductor chips 30 to 33. For connection with the bonding wires 90, the semiconductor chips 30 to 33 are stacked with displacements for the pads.

More in detail, the bonding wires 90 afford electrical connection between the pads 10p1 provided on the front surface of the wiring substrate 10 and pads (not shown) provided on the front surfaces of the semiconductor chips 30 to 33.

Furthermore, the sealing resin (resin layer) 91 seals the semiconductor chips 20 and 30 to 33, the bonding layers 40 to 43 and the member 50, the bonding wires 90, and the like. Thereby, the semiconductor device 1 is configured as one semiconductor package of the plurality of semiconductor chips 20 and 30 to 33 on the wiring substrate 10.

FIG. 2 is a plan view showing an example of positional relationship of the wiring substrate 10, the semiconductor chip 20, the bonding layer and the member 50 in FIG. 1. FIG. 2 is a view as a plane parallel to the surface F30a shown in FIG. 1 (see the A-A line in FIG. 1) which is viewed from an upper portion above the view plane of FIG. 1.

An outer edge of the bonding layer 40 (outer edge of the semiconductor chip 30) as viewed from a direction substantially perpendicular to the surface F10a is outward of an outer edge of the semiconductor chip 20. Namely, the semiconductor chip 30 is provided so as to coat (cover) the semiconductor chip 20 as viewed from the direction substantially perpendicular to the surface F10a.

The member 50 is provided on the outer periphery of the bonding layer 40 as viewed from the direction substantially perpendicular to the surface F10a. More in detail, the member 50 is provided so as to cover the outer periphery of the bonding layer 40 along the outer periphery of the bonding layer 40. Namely, the member 50 is provided between the bonding layer 40 and the sealing resin 91.

Moreover, the member 50 is composed of a material having higher strength than the sealing resin 91. Examples of the strength include a tensile strength, a bending strength, and a hardness. The tensile strength of the member 50 is higher than 10 kgf/mm², for example. This can restrain a crack from arising.

An example of the bonding layer 40 is a thermosetting adhesive agent. An example of a main component of the bonding layer 40 is an acrylic resin. An example of a thermal expansion coefficient of the bonding layer 40 is about 70 ppm/° C. at ambient temperature, and about 120 ppm/° C. at 260° C. Notably, a structure material of the bonding layer 40 is not limited to the above.

An example of the sealing resin 91 is a thermosetting resin. An example of a main component of the sealing resin 91 is an epoxy resin. An example of a thermal expansion coefficient of the sealing resin 91 is about 9 ppm/° C. at ambient temperature, and about 36 ppm/° C. at 260° C. An example of a bending strength of the sealing resin 91 is about 170 MPa at 30° C., and about 19 MPa at 260° C. Notably, a structure material of the sealing resin 91 is not limited to the above.

The member 50 is composed, for example, of silicon (Si). Notably, a structure material of the member 50 is not limited to silicon. For example, it only has to be a material having higher strength than the sealing resin 91. Moreover, the member 50 is still preferably composed of a material that can be processed into any shape. The member 50 may be composed of a resin, for example.

Next, a manufacturing method of a semiconductor device is described.

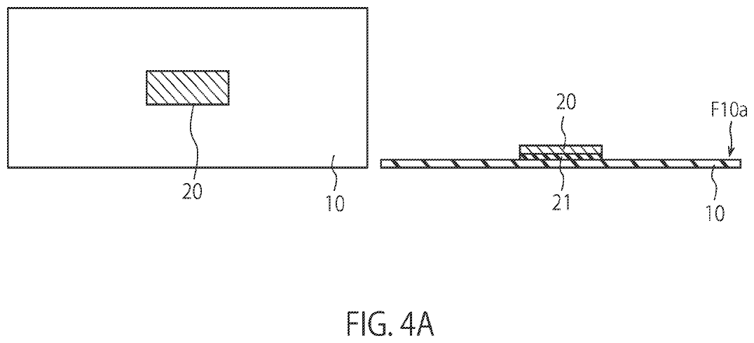

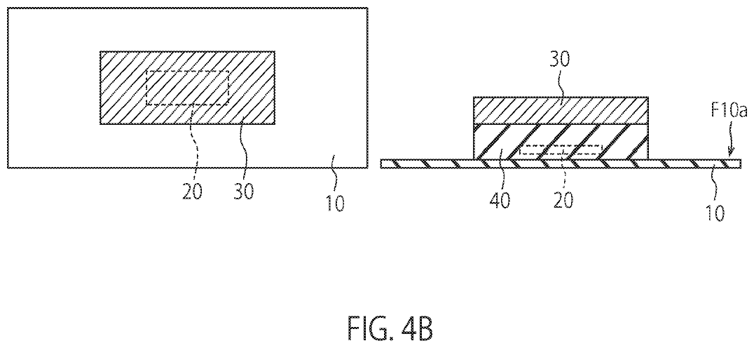

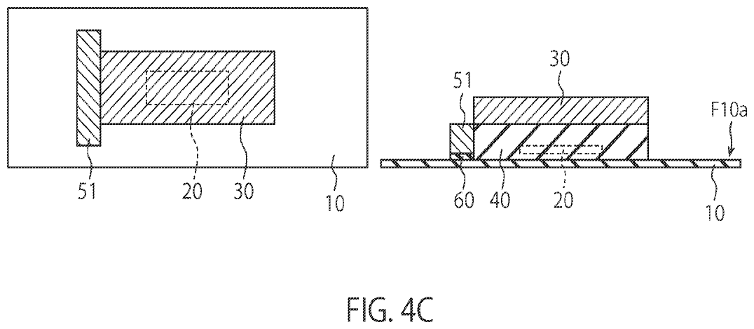

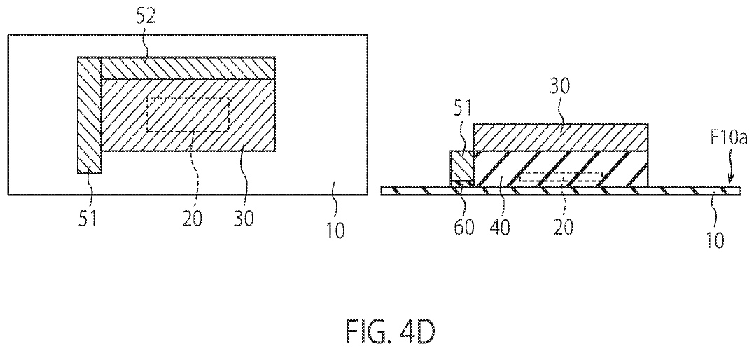

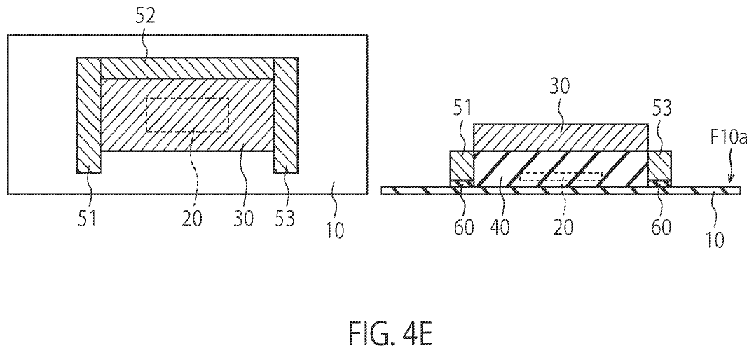

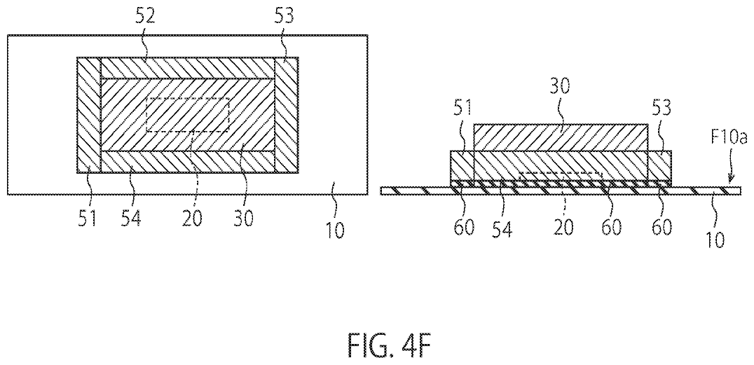

FIG. 3A to FIG. 3E show steps of dividing a wafer W on which the bonding layer 40 is pasted into separate semiconductor chips 30. FIG. 4A to FIG. 4F show steps of providing the semiconductor chips 20 and 30 and the member 50 on the wiring substrate 10.

FIG. 3A to FIG. 3E are views showing an example of a manufacturing method of the semiconductor device 1 according to the first embodiment.

As shown in FIG. 3A, a silicon wafer W (hereafter called wafer) on which a plurality of semiconductor parts are formed is prepared. The wafer W includes a third surface including the semiconductor parts and a fourth surface separate from the third surface in the Z-axis direction. Next, a surface protecting tape 110 is bonded onto the third surface of the wafer W.

Next, as shown in FIG. 3B, the wafer W is reversed. Then, the fourth surface of the wafer W is ground using a grinding stone 120, which is then retracted. This step is what is called a BSG (Back Side Grinding) step.

Next, as shown in FIG. 3C, the wafer W is reversed. Then, the fourth surface of the wafer W is bonded to a bonding resin pasted on a dicing ring 130. An example of the bonding resin is a DAF (Die Attach Film) 140a.

Next, as shown in FIG. 3D, the surface protecting tape 110 is peeled off from the third surface of the wafer W.

Next, as shown in FIG. 3E, the wafer W is diced using a blade 150. Dicing lines 160 are formed on the wafer W. Each dicing line 160 is formed along the X-axis direction and the Y-axis direction. The wafer W is separated into the plurality of semiconductor chips 30.

Notably, the DAF 140a as a second bonding layer is divided together with the wafer W into separate pieces to be bonding layers 40 each as a first bonding layer.

FIG. 4A to FIG. 4F are views showing an example of a manufacturing method of the semiconductor device 1 according to the first embodiment. The left side in each of FIG. 4A to FIG. 4F shows a top view. The right side in each of FIG. 4A to FIG. 4F shows a lateral view.

As shown in FIG. 4A, the semiconductor chip 20 is provided (mounted) on the surface F10a of the wiring substrate 10 via the bonding layer 21. The bonding layer 21 is pasted on the semiconductor chip 20 in advance. Thereafter, the bonding wires 22 are formed. Notably, the bonding layer 21, the bonding wires 22, the pads 10p2, and the like are omitted.

Next, as shown in FIG. 4B, the semiconductor chip 30 obtained by the division into separate pieces in the steps of FIG. 3A to FIG. 3E is provided on the surface F10a of the wiring substrate 10 via the bonding layer 40. More in detail, the semiconductor chip 30 is provided such that the semiconductor chip 20 and the bonding wires 22 are embedded in the bonding layer 40 provided on the surface F30a (such that the bonding layer 40 coats the semiconductor chip 20 and the bonding wires 22).

Notably, as mentioned above, the lateral surfaces of the bonding layer 40 are approximately parallel to the lateral surfaces of the semiconductor chip 30 existing between the surface F30a and the surface F30b. Moreover, the width of the bonding layer 40 is approximately equal to the width of the semiconductor chip 30.

Next, as shown in FIG. 4C, a member 51 is provided on the surface F10a of the wiring substrate 10 via the bonding layer 60. The bonding layer 60 is pasted on the member 51 in advance. For example, the member 51 is provided along one side (short side) of the semiconductor chip 30. The member 51 is a part of the member 50.

Next, as shown in FIG. 4D, a member 52 is provided on the surface F10a of the wiring substrate 10 via the bonding layer 60. The bonding layer 60 is pasted on the member 52 in advance. For example, the member 52 is provided along one side (long side) of the semiconductor chip 30. The member 52 is a part of the member 50.

Next, as shown in FIG. 4E, a member 53 is provided on the surface F10a of the wiring substrate 10 via the bonding layer 60. The bonding layer 60 is pasted on the member 53 in advance. For example, the member 53 is provided along one side (short side) of the semiconductor chip 30. The member 53 is a part of the member 50.

Next, as shown in FIG. 4F, a member 54 is provided on the surface F10a of the wiring substrate 10 via the bonding layer 60. The bonding layer 60 is pasted on the member 54 in advance. For example, the member 54 is provided along one side (long side) of the semiconductor chip 30. The member 54 is a part of the member 50.

As shown in FIG. 4F, the members 51 to 54 are provided along all of the sides of the semiconductor chip 30 (the outer periphery of the bonding layer 40). The members 51 to 54 correspond to the member 50 shown in FIG. 2. Notably, the order for providing the member 51 to 54 is not limited to that in the example shown in FIG. 4C to FIG. 4F.

As above, according to the first embodiment, the member 50 is provided on the outer periphery of the bonding layer 40 as viewed from the direction substantially perpendicular to the surface F10a. Since the member 50 is composed of the material having higher strength than the sealing resin 91, a crack can be restrained from arising due to tensile concentration, and the influence of a crack can be reduced.

### Comparative Example

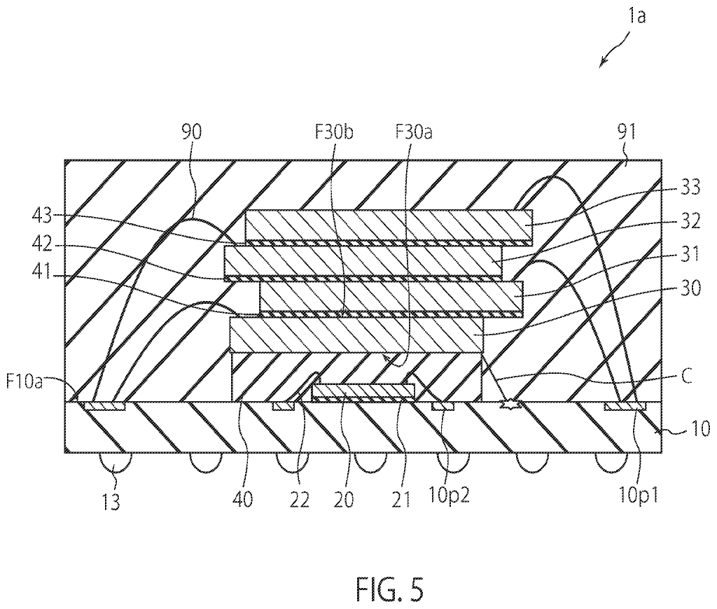

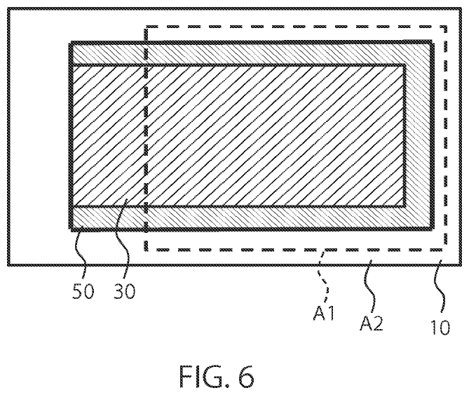

FIG. 5 is a cross sectional view showing an example of a configuration of a semiconductor device 1a according to a comparative example. The comparative example is different from the first embodiment in that the member 50 and the bonding layer 60 are not provided.

There is occasionally a case where a crack C arises in the example shown in FIG. 5. A region between the bonding layer 40 and the sealing resin 91 can become an origin of the crack C arising due to stress concentration caused by temperature change. In the example shown in FIG. 5, the crack C possibly arises with a boundary portion among the semiconductor chip 30, the bonding layer 40, and the sealing resin 91 being as the origin.

When the crack C advances to the wiring substrate 10, this results in a possibility of affecting wiring in the wiring substrate 10, which can cause electrical failures such as disconnection defects.

In contrast, with the first embodiment, by providing the member contact between the bonding layer 40 and the sealing resin 91 can be restrained. The member 50 higher in strength than the sealing resin 91 is provided on the periphery of the bonding layer 40, that is, between the bonding layer 40 and the sealing resin 91, and thereby, a crack can be restrained from arising.

Notably, in the example shown in FIG. 4F, the members 51 to 54 are provided with almost no gaps therebetween. Nevertheless, the member 50 does not have to be provided on part of the outer periphery of the bonding layer 40. Accordingly, the member 50 may be provided on at least part of the outer periphery of the bonding layer 40 as viewed from the direction substantially perpendicular to the surface F10a.

For example, there is a possibility that the influence of stress due to temperature change (expansion) varies due to the material, the structure, the shape, or the like of the bonding layer 40. As a result, this occasionally results in a case where a tendency of a crack arising varies depending on the position of contact between the bonding layer 40 and the sealing resin 91. In such a case, the member 50 only has to be arranged at the positions where a crack tends to arise, and the member does not have to be arranged at the other places. For example, when it is known in advance that a defect such as a crack tends to arise at the portions of the short sides of the semiconductor chip 30 in FIG. 4B to FIG. 4F, the members 51 and 53 arranged along the short sides only have to be provided, and the members 52 and 54 do not have to be provided.

### (Modification)

FIG. 6 is a plan view showing an example of positional relationship between the wiring substrate 10, the semiconductor chip 30, and the member 50 according to a modification.

The wiring substrate 10 occasionally has a region A1 inside which wiring is provided, and a region A2 inside which wiring is not provided. In FIG. 6, the region A2 is the region, on the wiring substrate 10, other than the region A1. Even when a crack advances into the region A2, disconnection defects do not arise. Accordingly, the member 50 does not have to be provided on an outer periphery, of the bonding layer 40, that is on the region A2 side (on a side, of the semiconductor chip 30, that is on the region A2 side) as viewed from the direction substantially perpendicular to the surface F10a. This can accordingly reduce material costs of the member 50. In the example shown in FIG. 6, the region A2 is on a side where the left short side of the semiconductor chip 20 exists. Accordingly, the member 50 is not provided on the side where the left short side of the semiconductor chip 20 exists.

### Second Embodiment

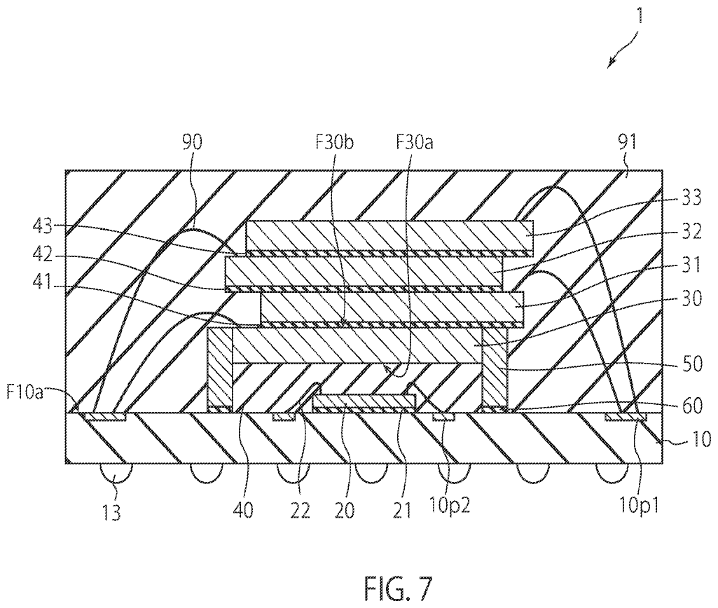

FIG. 7 is a cross sectional view showing an example of a configuration of a semiconductor device 1 according to a second embodiment. As compared with the first embodiment, the second embodiment has a different height of the upper surface of the member 50.

The height of the upper surface of the member 50 is larger than the height of the surface F30a of the semiconductor chip 30. More in detail, the height of the upper surface of the member 50 is a height of the surface F30b of the semiconductor chip 30. The member 50 functions as a spacer that supports the semiconductor chip 31 provided on the semiconductor chip 30. Thereby, the semiconductor chip 31 can be supported when the bonding wires 90 are formed onto the semiconductor chip 31. As a result, the influence of load and stress exerted during wire bonding can be reduced, and a crack can be restrained from arising.

The other configurations of the semiconductor device 1 according to the second embodiment are similar to the corresponding configurations of the semiconductor device 1 according to the first embodiment, and their detailed description is omitted. The semiconductor device 1 according to the second embodiment can attain the similar effects to those in the first embodiment.

### Third Embodiment

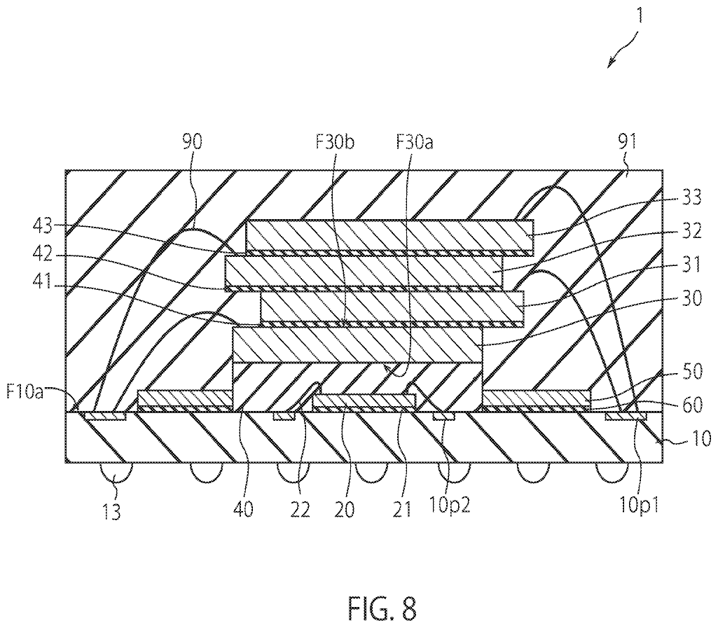

FIG. 8 is a cross sectional view showing an example of a configuration of a semiconductor device 1 according to a third embodiment. As compared with the first embodiment, the third embodiment has a different height of the upper surface of the member 50.

The height of the upper surface of the member 50 is lower than the surface F30a of the semiconductor chip 30. In this case, the volume of the member 50 can be reduced, and material costs can be reduced.

Even when the crack C shown in FIG. 5 arises, by the member 50 covering the surface F10a of the wiring substrate 10, the crack C can be caused not to reach the wiring substrate 10. Namely, the member 50 according to the third embodiment functions as a wiring protection member for the wiring substrate 10. Thereby, the influence of the crack C can be reduced.

For example, the member 50 is provided from the outer periphery of the bonding layer 40 to the pads 10p1. In order to protect the wiring, the member 50 is preferably provided over a wider range in parallel directions to the surface F10a. Nevertheless, in order not to be in contact with the bonding wires 90, the member 50 is preferably provided behind the pads 10p1 from the directions, among those, where the pads 10p1 exist (the right-left directions in the view plane of FIG. 8).

The other configurations of the semiconductor device 1 according to the third embodiment are similar to the corresponding configurations of the semiconductor device 1 according to the first embodiment, and their detailed description is omitted. The semiconductor device 1 according to the third embodiment can attain the similar effect to those in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate having a first surface;
a first semiconductor chip provided on the first surface;
a second semiconductor chip that is provided above the first semiconductor chip, has a second surface facing the first surface and the first semiconductor chip, and coats the first semiconductor chip as viewed from a direction substantially perpendicular to the first surface;
a first bonding layer provided between the second surface and both the first surface and the first semiconductor chip; and
a member provided on at least part of an outer periphery of the first bonding layer as viewed from the direction substantially perpendicular to the first surface.

2. The semiconductor device according to claim 1, wherein the first bonding layer includes an acrylic substance.

3. The semiconductor device according to claim 1, further comprising a resin layer that is provided on the first surface and coats the second semiconductor chip, the first bonding layer, and the member, wherein
a tensile strength of the member is higher than a tensile strength of the resin layer.

4. The semiconductor device according to claim 3, wherein the resin layer includes an epoxy resin.

5. The semiconductor device according to claim 1, wherein a height of an upper surface of the member is not less than a height of the second surface.

6. The semiconductor device according to claim 5, wherein the height of the upper surface of the member is a height of a third surface, of the second semiconductor chip, that is on an opposite side of the second surface.

7. The semiconductor device according to claim 6, further comprising
a third semiconductor chip provided on the second semiconductor chip, wherein
the member supports the third semiconductor chip.

8. The semiconductor device according to claim 1, wherein a height of an upper surface of the member is lower than the second surface.

9. The semiconductor device according to claim 8, further comprising:
a pad provided on the first surface of the substrate; and
a wire electrically connecting the pad and the second semiconductor chip, wherein
the member is provided from the outer periphery of the first bonding layer to the pad.

10. The semiconductor device according to claim 1, wherein
the substrate has a first region inside which wiring is provided, and a second region inside which wiring is not provided, and
the member is not provided on an outer periphery, of the first bonding layer, that is on the second region side as viewed from the direction substantially perpendicular to the first surface.

11. A manufacturing method of a semiconductor device, comprising:
providing a first semiconductor chip on a first surface of a substrate;
providing a second semiconductor chip on the first surface such that a first bonding layer provided on a second surface of the second semiconductor chip coats the first semiconductor chip; and
providing a member on at least part of an outer periphery of the first bonding layer as viewed from a direction substantially perpendicular to the first surface.

12. The manufacturing method of a semiconductor device according to claim 11, further comprising:
providing a second bonding layer on a fourth surface of a wafer having a third surface that a semiconductor element is formed on and the fourth surface that is on an opposite side to the third surface; and
forming the second semiconductor chip on the second surface of which the first bonding layer is provided, by dividing, together with the second bonding layer, the wafer into separate pieces.

13. The semiconductor device according to claim 2, further comprising
a resin layer that is provided on the first surface and coats the second semiconductor chip, the first bonding layer, and the member, wherein
a tensile strength of the member is higher than a tensile strength of the resin layer.

14. The semiconductor device according to claim 13, wherein the resin layer includes an epoxy resin.
